(19) United States
(12) Patent Application Publication
(10) Pub. No.: US 2015/0147845 A1
(43) Pub. Date: May 28, 2015

(54) DUAL SIDED EMBEDDED DIE AND FABRICATION OF SAME BACKGROUND

(71) Applicant: Texas Instruments Incorporated, Dallas, TX (US)

(72) Inventors: Anindya Poddar, Sunnyvale, CA (US); Mark Allen Gerber, Lucas, TX (US); Mutsumi Masumoto, Beppu (JP); Masamitsu Matsuura, Beppu (JP); Kengo Aoya, Beppu (JP); Takeshi Onogami, Beppu (JP)

(21) Appl. No.: 14/552,548

(22) Filed: Nov. 25, 2014

Related U.S. Application Data
(60) Provisional application No. 61/908,889, filed on Nov. 26, 2013.

(51) Int. Cl. H01L 25/00; H01L 21/304; H01L 21/683; H01L 21/3213; H01L 21/321; H01L 21/3105; H01L 21/768

(52) U.S. Cl. CPC H01L 25/50; H01L 21/31053; H01L 21/304; H01L 21/76802; H01L 21/76879; H01L 21/76883; H01L 21/32133; H01L 21/32139; H01L 21/32115; H01L 21/6836
USPC 438/107; 438/118

(57) ABSTRACT

Embodiments of the invention provide a method for forming a dual sided embedded die system. The method begins with starting material including a top surface and a bottom surface, a plurality of vias, a plurality of plated metal posts, die pads, and stiffeners. The surface are planarized to expose the included metal which is than selectively etching from die attach pad DAP areas to form cavities. Create a stiffener by using photo resist patterning and plating. Apply tacky tape. Attach a die. Laminate and grind. Remove tacky tape. Form redistribution layers RDLs and a solder mask. Mounting Surface Mount Devices.

### CROSS-REFERENCE TO RELATED APPLICATIONS

This application claims the benefit of priority under 35 U.S.C. §119(e) of U.S. Provisional Application 61/908,889, filed Nov. 26, 2013. Said application incorporated herein by reference.

### BACKGROUND

1. Field

Embodiments of the present invention are directed, in general, to semiconductor device packaging and, more specifically, dual sided embedded dies.

2. Background

Embedded die in organic substrates offer a compelling advantage for integration and a system in a package (SiP). Applications can be found in point of load power supplies, switching regulators, mobile applications, and anywhere there is a need to integrate multiple die and passives.

Several products such as uSiP, nano Module, and etc. are constructed using an embedded IC, with passives surface mounted on the top side of the laminate and package land pads on the bottom side. This offers a path to integration beyond simple Fan-out Wafer Level Packaging (FOWLP) like approaches.

FIG. 1 is Illustrative of a typical approach to embedding with two sided routing. Typical approaches to embedding with two sided routing may use drilled vias to connect the top and bottom sides. However, one consequence of this flow is the need to use die attach materials, copper Cu sheets, and drilled or laser via formation to create interconnects to the die.

### SUMMARY

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

In accordance with an embodiment of the application, a dual sided embedded die system includes vias, plated copper Cu posts for vias, die pads, and stiffeners. The top and bottom surfaces of the starting material are planarized to expose the Cu posts. The Cu is selectively etched from Die Attach Pad (DAP) areas to form cavities. A stiffener is created by photo or laser resist patterning and plating. A leveling is provided. Tacky tape or a backside Stiffener-core is applied to the bottom of the assembly. The backside Stiffener-core may be composed of metal. A die is attached face down to DAP. The assembly is laminated assembly with a film. The assembly is grinded to expose the vias. The grinding may include co-grinding of silicon. The tacky tape is removed. A first redistribution layer (RDL) is formed on the backside of the assembly by sputtering a seed layer on the backside of the assembly. The assembly is plated than patterned with photoresist. The plating is etched and photoresist is removed. A seed layer is exposed. A second RDL is formed on the frontside of the assembly by sputtering a seed layer on the backside of the assembly. The assembly is plated and patterned again with photoresist. The plating is etched and photoresist is removed. The seed layer is exposed. A solder mask (SMSK) is formed. The assembly is finished. Surface Mount Devices (SMDs) are mounted where desired.

In accordance with another embodiment of the application, a method to form a dual sided embedded die assembly starts with a starting material including vias, plated Cu posts for vias, die pads, and stiffeners. The top and bottom surfaces of the starting material are planarized to expose the included the Cu posts. The Cu is; selectively etched from die attach pad DAP areas to form cavities. A stiffener is created by photoresist or laser patterning and plating. Leveling is provided. A tacky tape or a backside Stiffener-core is applied to the bottom of the assembly. The backside Stiffener-core may be composed of metal. A die is attached face down to DAP. The assembly is laminated with a film. The assembly is grinded to expose vias. The grinding may include co-grinding of silicon. The tacky tape is removed. A solder mask (SMSK) is formed.

### DESCRIPTION OF THE VIEWS OF THE DRAWING

FIG. 1 is Illustrative of a typical approach to embedding with two-sided routing in accordance with the prior art.

FIG. 2 is illustrative of steps in the fabrication of integrated circuits formed according to an embodiment.

FIG. 3 is illustrative of steps in forming a redistribution layer (RDL) according to the embodiment of FIG. 2.

FIG. 4 is illustrative of steps in the fabrication of integrated circuits formed according to another embodiment.

FIG. 5 is illustrative of steps in forming a redistribution layer (RDL) according to the embodiment of FIG. 4.

FIG. 6 is illustrative of steps in the fabrication of integrated circuits formed according to another embodiment.

FIG. 7 is illustrative of steps in forming a redistribution layer (RDL) according to the embodiment of FIG. 6.

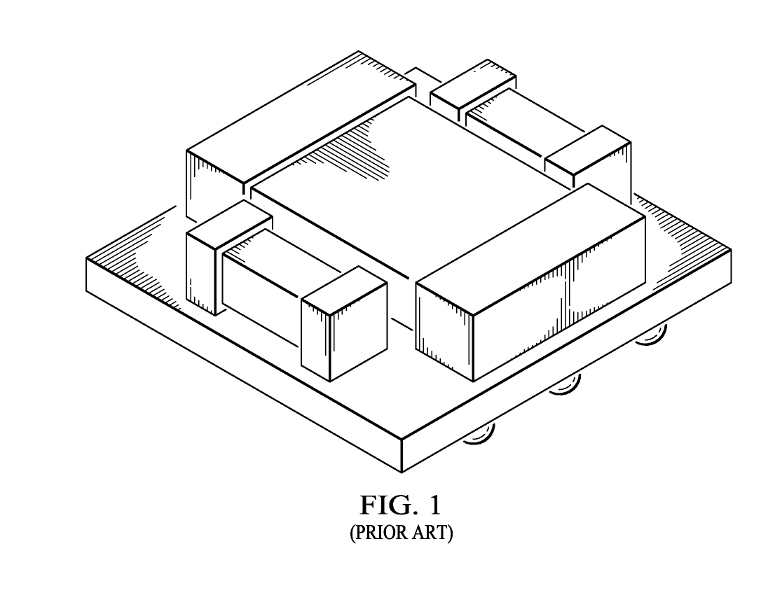

In the drawings, like reference numerals are sometimes used to designate like structural elements. It should also be appreciated that the depictions in the figures are diagrammatic and not to scale.

### DETAILED DESCRIPTION OF EXAMPLE EMBODIMENTS

The embodiments of the invention now will be described more fully hereinafter with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art. One skilled in the art may be able to use the various embodiments of the invention. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The embodiments are not limited by the illustrated ordering of acts or events, as some acts may occur in different orders and/or concurrently with other acts or events. Furthermore, not all illustrated acts or events are required to implement a methodology in accordance with the embodiments.

The embodiments of the invention offer a cost effective scalable integration solution for embedded die with dual sided interconnect on the package.

Vias are created in the prior art using mechanical drilling or laser. Mechanically drilled vias have a problem with having a coarse pitch. Laser vias are slow and expensive. Instead of using drilled or laser vias, the embodiments of the Invention provide a plated substrate to create very fine pitch vias and support structures. The vias are formed before component embedding, which simplifies the process flow and cost. The plated processes are photolithigraphically based and offer a far better resolution and lower cost.

The support structure created this way also offers better mechanical stability and eliminates the need for epoxy attach during embedding in the package structure process and flow simplification.

Typical approaches to embedding with two sided routing uses drilled vias to connect the top and bottom sides. However, one consequence of this process is the need to use Cu sheets, mechanical drill to make connections to the two sides, laser via formation to create interconnects to the die, etc., all of which limit the ability to have fine pitch die with high yields.

Embodiments of the invention leverage the advantages of a die attach free, laser free, direct contact to Al pads on die—while enabling fine pitch vias and dual sided connections.

In an embodiment of the invention, instead of starting with a solid Cu foil or a simple Cu carrier with cavities, the starting material is replaced with either etched Cu cavities on laminate or with half (½) etch Cu carriers that have pre-formed vias. Use of plated vias in a laminate carrier enables fine pitch via formation. Accurate cavity formation using photolithography processes allows precise die location with respect to vias.

The embodiments may use panel level chemical mechanical planarizing CMP or plasma thinning to expose the vias and then form routing layers on top and bottom side of the die.

Embodiments using pre-formed vias, use etched out cavities for die, or use of CMP or plasma thinning to expose vias. All techniques provide improved alignment accuracy, lower cost and finer pitch.

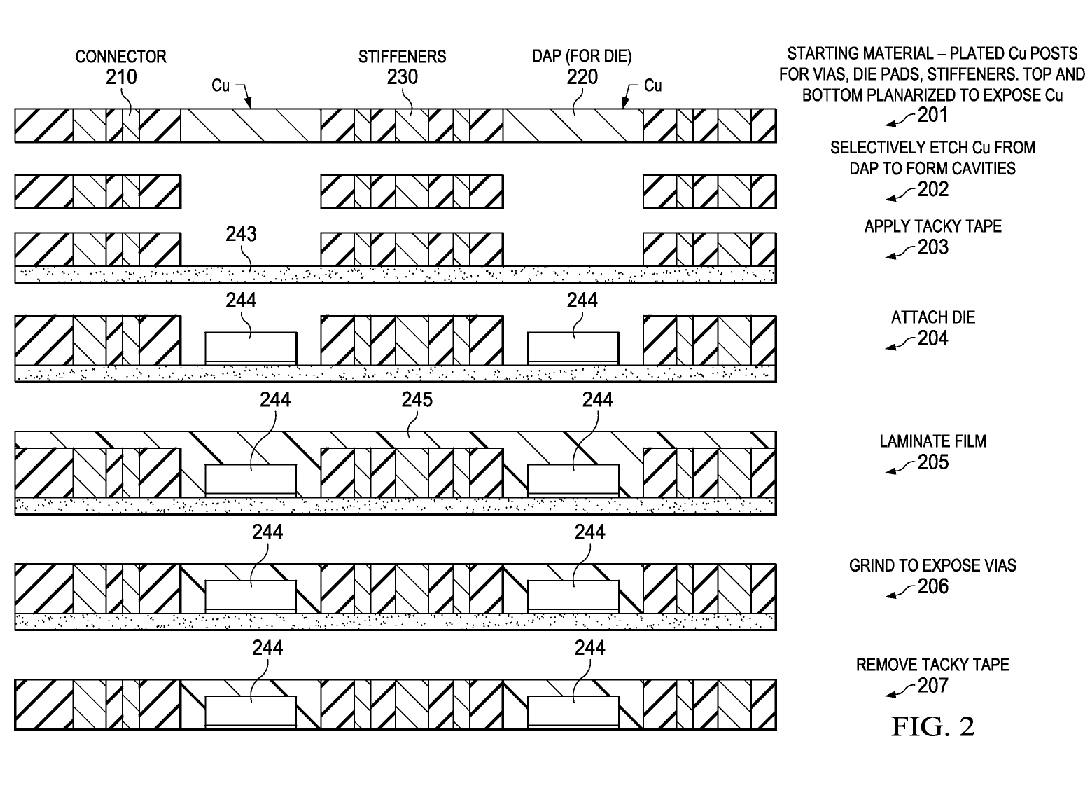

FIG. 2 is illustrative of a method flow in accordance with an embodiment.

At step 201, the starting material is plated vias, Cu posts for, connectors 210 DAP die pads 220, and stiffeners 230. The Target thickness is approximately 80 μm to 1000 μm tall including the uncured epoxy. The top surface and the bottom surface of the starting material are planarized to expose Cu.

At 202, selectively etch Cu from DAP to form cavities. A stiffener may be created by photo/laser resist patterning and plating. Leveling is preferred. An alternative is to use laser created vias including Cu plating.

At 203, apply tacky tape 243 or a backside Stiffener-core, which may be composed of metal.

At 204, Attach die 244, face down to DAP. The die thickness may range from 50 μm to 800 μm.

At 205, laminate assembly with a film 245. Possible films include ABF, HBI, or PI film.

At 206, grind assembly to expose vias. Grinding may include co-grinding of Silicon.

At 207, remove tacky tape.

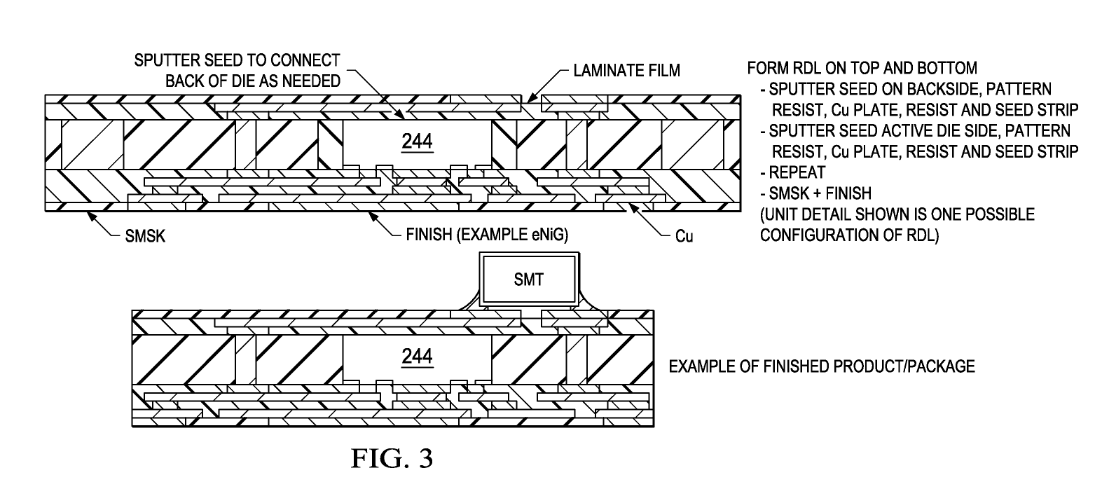

FIG. 3 is illustrative of forming a first redistribution layer (RDL) on the backside of the assembly of FIG. 2 by sputtering a seed layer on the backside of the assembly. The assembly is plated (with for example copper Cu) and patterned with photoresist. Etching is performed to remove the photoresist and the exposed the seed layer.

A second RDL is formed on the frontside of the assembly by sputtering a seed layer on the frontside of the assembly, patterning with photoresist. Etching removes the photoresist and the exposes the seed layer.

A solder mask (SMSK) is applied and the assembly finished.

A surface mount device (SMT) is mounted where desired.

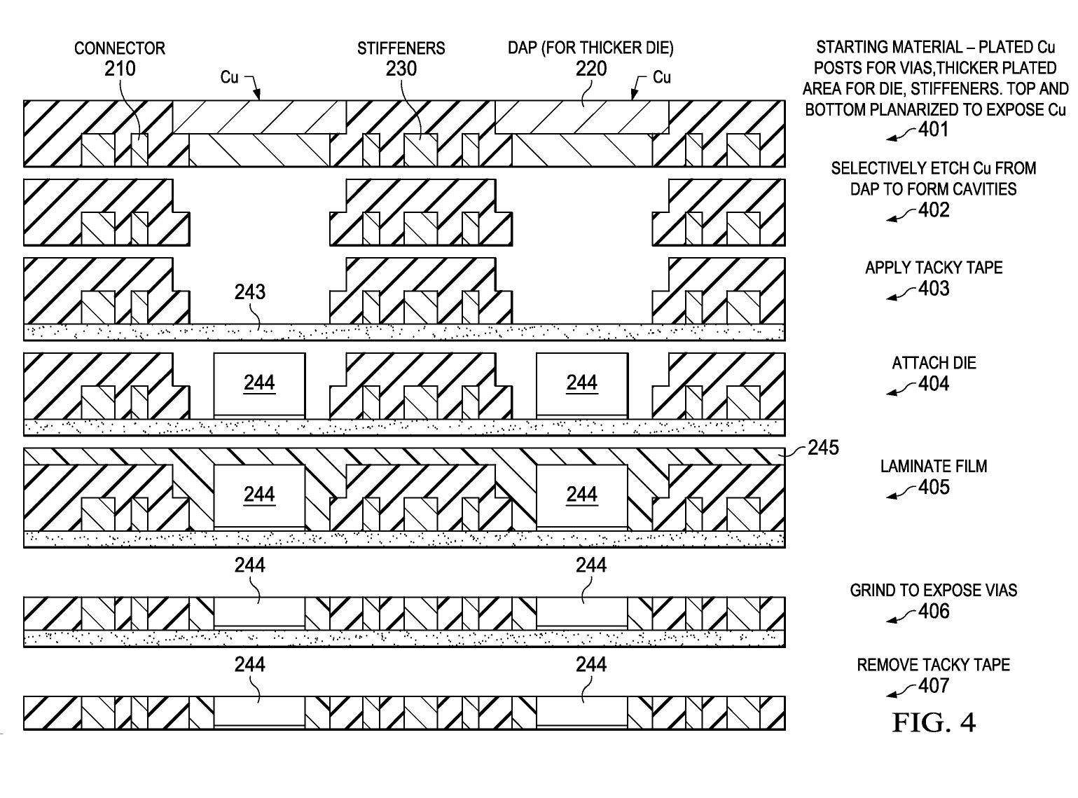

FIG. 4 is illustrative a method flow in accordance with another embodiment.

At step 401, the starting material is plated vias with Cu posts for connectors 210, die pads, and stiffeners 230. The target thickness may be approximately 80 μm to 1000 μm tall including the uncured epoxy. The top and bottom of the starting material may be planarized to expose Cu.

At 402, selectively etch the copper Cu from DAP to form cavities. A stiffener may be created by photo or laser resist patterning and plating. A leveling may also be performed. An alternative would be to use laser created vias including Cu plating.

At 403, apply tacky tape 243 or a backside Stiffener-core, which may be composed of metal.

At 404, attach die 244 face down to DAP 420. Die thickness may range from 50 μm to 800 μm.

At 405, laminate assembly with a film 245. Some film examples are ABF, HBI, or PI film.

At 406, grind assembly expose vias, which may include co-grinding of silicon.

At 407, remove tacky tape.

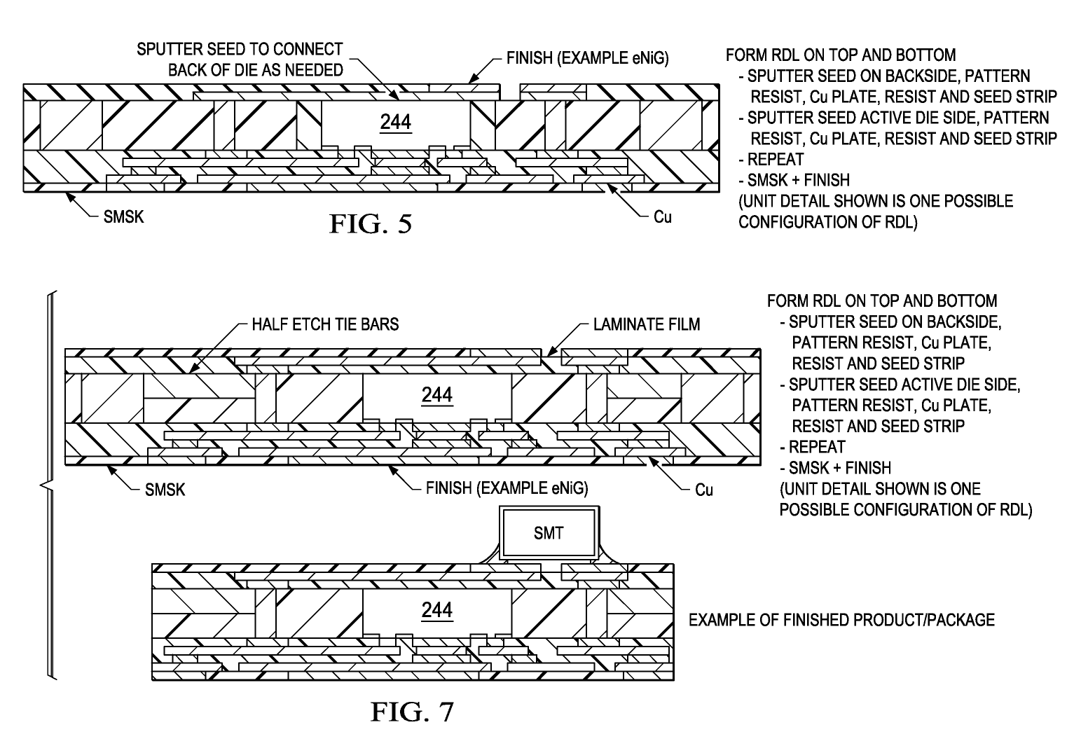

FIG. 5 is illustrative of forming a first redistribution layer (RDL) on the backside of the assembly of FIG. 4 by sputtering a seed layer on the backside of the assembly. The assembly is plated (with for example copper Cu) and patterned with photoresist. Etching is performed to remove the photoresist and the exposed the seed layer.

A second RDL is formed on the frontside of the assembly by sputtering a seed layer on the frontside of the assembly, patterning with photoresist. Etching removes the photoresist and the exposes the seed layer.

A solder mask (SMSK) is applied and the assembly finished.

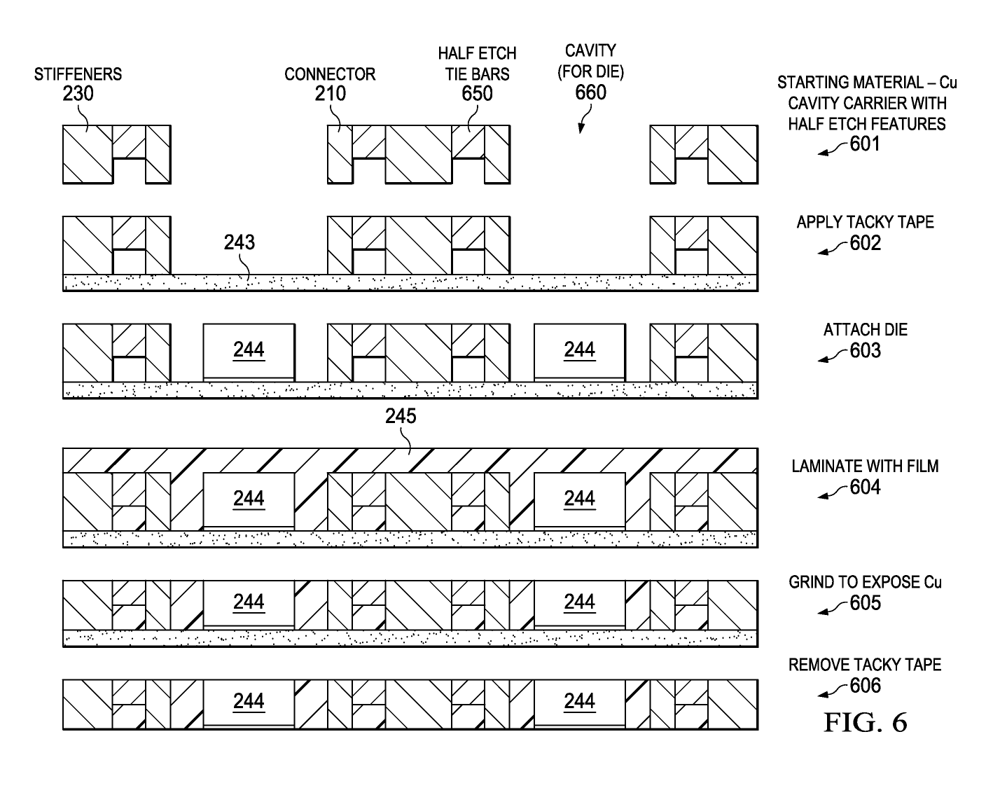

FIG. 6 is illustrative of another method flow in accordance with yet another embodiment.

At step 601, the starting material is copper Cu cavity carrier with half ½ etch features approximately 80 μm to 1000 μm thick. This assembly process works well with coarse pitch vias that may all be connected with tie bars 650.

At 602, apply tacky tape 243.

At 603, attach die 244 face down.

At 604, laminate assembly with a film 245. Some film examples are ABF, HBI, or PI film.

At 605, grind assembly expose copper Cu.

At 606, remove tacky tape.

FIG. 7 is illustrative of forming a first redistribution layer (RDL) on the backside of the assembly of FIG. 4 by sputtering a seed layer on the backside of the assembly. The assembly is plated (with for example copper Cu) and patterned with photoresist. Etching is performed to remove the photoresist and the exposed the seed layer.

A second RDL is formed on the frontside of the assembly by sputtering a seed layer on the frontside of the assembly, patterning with photoresist. Etching removes the photoresist and the exposes the seed layer.

A surface mount device (SMT) is mounted where desired.

The flows provided by the embodiments allow low cost fine pitch connections and eliminates epoxy adhesives.

While various embodiments of the invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A method of forming a dual sided embedded die system, comprising:
providing a starting material including a top surface and a bottom surface, a plurality of vias, a plurality of plated metal posts, die pads, and stiffeners;
planarizing the top and bottom surfaces of the starting material to expose the included metal;
selectively etching the metal from die attach pad DAP areas to form a plurality of cavities;
photo resist patterning and plating to create a stiffener;
applying tacky tape to the bottom of the assembly;
attaching a die to DAP;
laminating assembly with a film;
grinding assembly to expose a the vias, wherein the grinding includes co-grinding of Silicon;
removing tacky tape;
forming a first redistribution layer (RDL) on a backside of the assembly;
forming a second RDL on the frontside of the assembly;
forming a solder mask (SMSK) and finishing; and
mounting Surface Mount Devices (SMD).

2. The method of claim 1, wherein the target thickness of the starting material is approximately 80 μm to 1000 μm tall including uncured epoxy.

3. The method of claim 1, wherein a laser is used to create the plurality of vias.

4. The method of claim 1, wherein the die thickness is of a range from 50 μm to 800 μm.

5. The method of claim 1, wherein a laser is used to create a plurality of vias.

6. The method of claim 1, wherein laser resistant patterning and plating is used to create the stiffener.

7. The method of claim 1, further comprising applying a backside Stiffener-core to the bottom of the assembly.

8. The method of claim 1, wherein the grinding includes co-grinding of silicon.

9. The method of claim 1, wherein the metal comprises copper Cu.

10. The method of claim 6, wherein the backside Stiffner-core is composed of a second metal.

11. The method of claim 9, wherein the second metal comprises copper Cu.

12. The method of claim 1, wherein forming RDLs comprising:
sputtering a seed layer on the backside of the assembly;
Cu plating the assembly;
patterning with a photoresist;
etching the Cu plating; and
removing the photoresist and exposing the seed layer.

13. A method of forming a dual sided embedded die assembly, comprising:
providing a starting material including plated Cu posts for vias, die pads, and stiffeners;
planarizing the top and bottom surfaces of the starting material to expose the included Cu;
selectively etching the Cu from die attach pad (DAP) areas to form cavities, wherein a stiffner is created by photo /laser resist patterning and plating, wherein leveling is included;
applying tacky tape or a backside Stiffner-core to the bottom of the assembly, wherein the backside Stiffner-core is composed of metal;
attaching a die, face down to DAP;
laminating assembly with a film;
grinding assembly expose vias, wherein the grinding includes co-grinding of silicon;
removing tacky tape; and
forming a solder mask (SMSK) and finishing.

14. The method of claim 13, wherein the target thickness of the starting material is in a range from 80 μm to 1000 μm tall including uncured epoxy.

15. The method of claim 13, wherein a laser is used to create the vias and also include copper Cu plating.

16. The method of claim 13, wherein the die thickness is in a range from 50 μm to 800 μm.
